(19) United States
(12) Patent Application Publication
(10) Pub. No.: US 2007/0052009 A1
(43) Pub. Date: Mar. 8, 2007

(54) PHASE CHANGE MEMORY DEVICE AND METHOD OF MAKING SAME

(75) Inventors: Ya-Hong Xie, Beverly Hills, CA (US); Tae-Sik Yoon, Seoul (KR); Zuoming Zhao, Alhambra, CA (US)

Correspondence Address: Vista IP Law Group LLP, 9th Floor, 2040 Main Street, Irvine, CA, 92614, US

(73) Assignee: The Regents of the University of California, Oakland, CA (US)

(21) Appl. No.: 11/470,216

(22) Filed: Sep. 5, 2006

Related U.S. Application Data
(60) Provisional application No. 60/714,957, filed on Sep. 7, 2005.

(51) Int. Cl. H01L 29/788

(52) U.S. Cl. 257/318

(57) ABSTRACT

A phase change random access memory (PRAM) element is provided that is driven by a MOSFET. The MOSFET includes, for example, a source region, a drain region, and a gate electrode disposed between the source region and the drain region. An insulator layer (e.g., oxide layer) separates the gate electrode from contact with the region of the substrate between the source and drain regions. A first electrode contact is coupled to the drain region of the MOSFET at one end and terminates at a surface. The surface of the first electrode contact is coated with a phase change material. A second electrode contact is provided having a surface coated with a layer of phase change material. The PRAM element includes at least one columnar member formed from a phase change material interposed between the phase change material layer of the first electrode and phase change material layer of the second electrode. In certain embodiments, a plurality of columnar members are interposed between the upper and lower layers of phase change material. Each of the columnar members are separated from one another via an insulator material.

### REFERENCE TO RELATED APPLICATIONS

This Application claims priority to U.S. Provisional Patent Application No. 60/714,957 filed on Sep. 7, 2005. U.S. Provisional Patent Application No. 60/714,957 is incorporated by reference as if set forth fully herein.

### FIELD OF THE INVENTION

The field of the invention generally relates to memory devices. In particular, the field of the invention relates to so-called phase change memory devices that incorporate phase change materials.

### BACKGROUND OF THE INVENTION

Semiconductor-based memory devices are now ubiquitous in a large variety of electronic products. These include, for example, personal computers, cameras, MP3 players, mobile phones, and other consumer electronic devices. Many of these devices utilize so-called non-volatile memory which does not require constant or periodic recharging or refreshing. For example, new memory technologies such as FLASH (NAND and NOR)-based memory is increasingly being used in a wide variety of electronic devices. FLASH memory is a solid-state replacement for magnetic memory and utilizes a transistor with a specially engineered floating gate that maintains charge states. Unfortunately, as is the case with most semiconductor based devices, scalability becomes a serious concern as ever smaller devices are formed in greater densities on a given footprint of available semiconductor real estate. For instance, with respect to FLASH memory, serious technological hurdles exist beyond the 65 nm technology node that is expected to occur in 2007.

Additional next generation non-volatile memories have been proposed that may potentially solve the scalability problems that afflict current generation devices. One such memory is phase-change RAM (PRAM). PRAM operates by utilizing a material that can reversibly switch between crystalline and amorphous phases in response to thermal heating (e.g., Joule heating). Typically, a short pulse of electrical current is applied to the phase change material to toggle between the crystalline and amorphous states. While PRAM devices do offer potential scalability advantages over existing memories there are still a number of challenges. First, PRAM devices are in their infancy and require additional investigation into appropriate materials and manufacturing processes. Second, many PRAM devices need relatively large write currents.

Another problem inherent in all PRAM devices is the requirement to contain the localized heating in the device that is used to toggle the phase change material between the crystalline and amorphous states. For example, as PRAM devices are scaled down to even small sizes, it becomes increasing harder to contain thermal cross-talk between adjacent memory cells. Finally, existing PRAM devices uses a phase change material that is in contact with a dissimilar material such as a metal. Repeated heating of the phase change material that is in contact with a metal (or metal alloy) will often result in metal migration which adversely affects the long-term reliability of the device, i.e., alloy-induced failure.

There thus is a need for a PRAM device and method of making the same that is able to provide scalability below the sub-micron range with less power consumption. In addition, there is a need for PRAM devices that can effectively isolate or contain thermal heat generated during the Joule heating process. There further is a need for PRAM devices that do not suffer from alloy-induced failures.

### SUMMARY OF THE INVENTION

In a first aspect of the invention, a PRAM element is provided that is driven by a MOSFET. The MOSFET is formed within a substrate, and includes, for example, a source region, a drain region, and a gate electrode disposed between the source region and the drain region. An insulator layer (e.g., oxide layer) separates the gate electrode from contact with the region of the substrate between the source and drain regions. A first electrode contact is electrically coupled to the drain region of the MOSFET at one end and terminates at a surface. The surface of the first electrode contact is coated with a phase change material. A second electrode contact is provided having a surface coated with a layer of phase change material. The PRAM element includes at least one columnar member formed from a phase change material interposed between the phase change material layer of the first electrode and phase change material layer of the second electrode. In certain embodiments, a plurality of columnar members are interposed between the upper and lower layers of phase change material. Each of the columnar members is separated from one another via an insulator material.

In another aspect of the invention, a method of making a memory cell includes providing a substrate including a source region, a drain region, and a gate electrode disposed between the source region and the drain region and separated from the source and drain regions via an insulator layer (e.g., oxide layer). A first electrode contact is provided that is coupled to the drain region at one end and terminates in a surface. The surface of the first electrode contact is coated with a layer of phase change material. An insulating layer is then formed over the layer of phase change material. The insulating layer is then patterned with at least one hole. The at least one hole is then filled with the phase change material. The insulating layer is then coated with a layer (e.g., top layer) of phase change material. A second electrode contact is provided on the layer of phase change material that overlays the patterned insulating layer.

In some aspects of the invention, the plurality of holes in the insulating layer is formed by using a self-assembled di-block copolymer layer that is applied to a surface of the insulating layer. One of the blocks of the di-block system is removed to leave a pattern of holes. The pattern is then transferred to the underlying insulating layer by use of an etching process, for example, reactive ion etching. Still other techniques may be employed to form the pattern of holes within the insulating layer. For example, nano-imprinting, electron beam (“e-beam”) lithography, and ion patterning may also be used.

In another aspect of the invention, a method of making a memory cell having a PRAM element driven by a MOSFET includes forming a bottom electrode contact electrically coupled to a drain region of the MOSFET. The upper surface of the bottom electrode contact is coated with a layer of phase change material. An insulating layer is formed over the layer of phase change material. A single hole or multiple hole patterns can be formed into the insulating layer using an array of techniques. One such technique can be that a self-assembled di-block copolymer layer is applied over the insulating layer and one block of the di-block copolymer layer is removed so as to form a patterned layer having at least one hole. The now formed pattern is then transferred to the underlying insulating layer. The at least one hole in the insulating layer are then filled with phase change material. A layer of phase change material is then deposited over the insulating layer. Finally, a top electrode contact is provided on the layer of phase change material disposed on the patterned insulating layer.

### BRIEF DESCRIPTION OF THE DRAWINGS

FIG. 1 illustrates a cross-sectional view of a PRAM element according to one embodiment.

FIG. 2 illustrates a cross-sectional view of a MOSFET having a bottom electrode contact in electrical contact with the drain region of the MOS element.

FIG. 3 illustrates a cross-sectional view of a MOSFET having a layer of phase change material in contact with the bottom electrode contact. An insulating layer is formed over the top of the phase change layer. A di-block copolymer layer is then formed on top of the insulating layer.

FIG. 4 illustrates a cross-sectional view of the structure of FIG. 3 with one block of the di-block copolymer being removed so as to leave a pattern of holes therein.

FIG. 5 illustrates a cross-sectional view of the structure of FIG. 4, wherein the pattern of holes is transferred to the underlying insulating layer. The remaining polymer layer is also shown as being removed from the structure.

FIG. 6 illustrates a top down view the structure of FIG. 5 showing the hole patterning in the insulating layer. The phase change material located beneath the insulating layer is obscured from view. FIG. 6 also illustrates the outline of the bottom electrode contact.

FIG. 7 illustrates a cross-sectional view of the structure of FIGS. 5 and 6 with the plurality of holes being filled with phase change material. A top or overlying layer of phase change material is applied over the plurality of holes.

FIG. 8 illustrates a cross-sectional view of the structure of FIG. 7 with the addition of a top electrode contact on the upper phase change material layer. In addition, the region containing the phase change material is reduced to an area between the bottom electrode contact and the top electrode contact.

FIG. 9 illustrates a cross-sectional view of a plurality of columnar members interspersed in a pattern within an insulator. The columnar members are interposed between lower and upper layers of phase change materials. The lower and upper layers of phase change materials are interposed between bottom and top electrode contacts, respectively. The bottom and top electrode contacts are dimensioned the same as the region containing the columnar members.

FIG. 10 is a partial cross-sectional view of a region of the PRAM element illustrating the columnar members being interposed between a bottom electrode contact and a top electrode contact.

FIG. 11 is a cross-sectional view of a MOSFET illustrating so called “noodle” type holes or strands being formed in lateral line patterns (e.g., horizontal) within a di-block copolymer system that is disposed on top of an insulator.

FIG. 12 is cross-sectional side view of the MOSFET of FIG. 11 illustrating the transfer of the pattern from the di-block copolymer layer to the underlying insulating layer.

FIG. 13 is a top down plan view of the MOSFET of FIG. 12.

FIG. 14 is a cross-sectional view of the MOSFET of FIGS. 12 and 13 with the empty lanes or lines being filled with phase change material.

FIG. 15 is a top down plan view of the MOSFET of FIG. 12.

FIG. 16 is a top down plan view of the final PRAM element showing the addition of the top electrode contact.

### DETAILED DESCRIPTION OF THE PREFERRED EMBODIMENTS

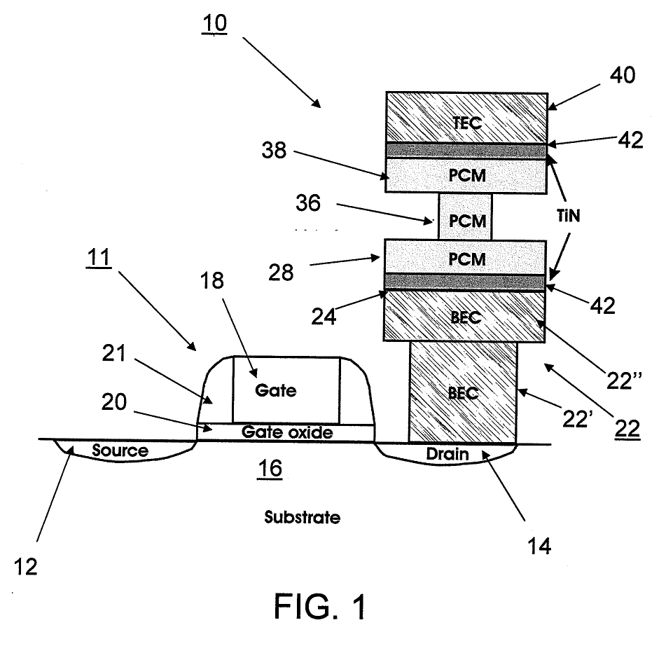

FIG. 1 illustrates a phase change random access memory (PRAM) element 10 or cell including a metal-oxide-semiconductor field-effect transistor (MOSFET) 11. The MOSFET 11 generally includes a source region 12 and a drain region 14 formed within a substrate 16 such as, for example, silicon. A gate electrode 18, which is typically in the form of a conductive line or trace is contained within an insulator 21 between the source and drain regions 12, 14 of the substrate 16. As seen in FIG. 1, the gate electrode 18 as well as the first electrode contact 22 are contained within the insulator 21. The gate electrode 18 is separated from the substrate 16 via an insulator 20 such as, for example, an oxide material (e.g., silicon dioxide). A first electrode contact 22 is shown in electrical contact with the drain region 14 of the MOS element 10. The first electrode contact 22 may be formed from an conductive interconnect line or trace including a conductive metal such as, for instance, tungsten, molybdenum, or tantalum. The first electrode contact 22 is disposed generally perpendicular to the plane of the substrate 16 (e.g., in a vertical direction as illustrated in FIG. 1) whereby the components of the PRAM element 10 may be built in a stacking or vertical fashion. The PRAM element 10 includes a resistive phase change material resistive element (described in more detail below) that is directly driven by the MOSFET 11. Still referring to FIG. 1, the first electrode contact 22 is a bottom electrode contact (BEC). The bottom electrode contact may include a generally post-like or vertical portion 22′ and horizontal layer 22″ that overlays the vertical portion 22′.

Still referring to FIG. 1, the bottom electrode contact (e.g., first electrode contact 22) has an upper surface 24. An optional diffusion barrier 42 is shown disposed as a layer on top of the bottom electrode contact 22. The optional diffusion barrier 42 is a thin layer of material that prevents or reduces metal migration into the phase change material. For example, the diffusion barrier 42 may be a thin layer of titanium nitride (TiN) or tungsten nitride (WN). Of course, the diffusion barrier 42 is optional and may be omitted entirely. A layer of phase change material 28 is then disposed over the top of the optional diffusion barrier 42. In the case where the diffusion barrier 42 is omitted, the layer of phase change material 28 would be disposed directly on top of the upper surface 24 of the bottom electrode contact 22. The layer 28 of phase change material may have a thickness within the range of about 1 nm to about 1000 nm. The phase change material used in the layer 28 may be formed from any number of materials and compounds used in phase change applications. These include, by way of example, chalcogenides. Exemplary compounds include, for example, GeSbTe, AgInSbTe, InSe, SbSe, SbTe, InSbSe, InSbTe, GeSbSe, GeSbTeSe, and AgInSbSeTe. The aforementioned compounds may be present in any ratio or stoichiometry in which the compound exhibits the ability to reversibly transition between crystalline and amorphous states. One such compound, GeSbTe (GST), is commonly found having the following chemical formula: Ge₂Sb₂Te₅.

As seen in FIG. 1, at least one columnar member 36 formed from a phase change material is disposed on the layer 28. The at least one columnar member 36 acts as a resistive element in the PRAM element 10 and thus is switched back and for the between the crystalline and amorphous states. The at least one columnar member 36 may be formed from the same material used to form the layer 28. In some embodiments, the at least one columnar member 36 may be a single columnar member 36 interposed between the lower layer 28 and an upper layer 38 also formed from the same phase change material. The upper layer 38 may have a thickness that is the same or substantially similar to the thickness of the lower layer 28. In still other embodiments, there are multiple columnar members 36 located between the layers 28, 38. FIG. 1 illustrates a single columnar member 36 formed between layers 28, 38.

Still referring to FIG. 1, the columnar member 36 may be dimensioned such that its width (or in some cases diameter) is less than the lateral dimension of the layers 28, 38. In this regard, the columnar member 36 is the smallest and most resistive part of the device 10. When multiple columnar members 36 are used, each columnar member 36 is separated by an insulator 38 (as shown in later FIGS.) having a low thermal conductivity value. The insulator 38 acts as a thermal cage that contains Joule heating within the individual columnar members 36.

A second electrode contact 40 is electrically coupled to an upper side or end of the columnar member 36 via the upper layer 38 of phase change material. In this regard, the second electrode contact 40 may take the form of a top electrode contact (TEC). The top electrode contact 40 may be formed of the same materials described above with respect to the first electrode contact 22. An optional diffusion barrier 42, as is shown in FIG. 1, may be interposed between the bottom surface of the top electrode contact 40 and the upper layer 38 of phase change material. In the case where the optional diffusion barrier 42 is not used, the top electrode contact 40 directly contacts the upper layer 38.

The upper layer 38 of phase change material generally has a larger lateral dimension than the width (or diameter as the case may be) of the columnar member 36. In certain embodiments, such as that illustrated in FIG. 1, the lateral dimension of the upper layer 38 is substantially the same as the lateral dimension as the lower layer 28. In embodiments such as the one illustrated in FIG. 1 it is preferably such that the cross-sectional area of the columnar member 36 is less than the cross-sectional area of the lower and upper layers 28, 38. Similarly, as is shown in FIG. 1, the cross-sectional area of the columnar member 36 is less than the cross-sectional area of the first and second electrical contacts 22, 40.

While FIG. 1 illustrates a single columnar member 36 interposed between the lower layer 28 and upper layer 38 of phase change materials it should be understood that a plurality of such columnar members 36 may be located or interposed between these two layers 28, 38. When multiple columnar members 36 are used the PRAM element 10 functions in multi bit/cell (MLC) operation.

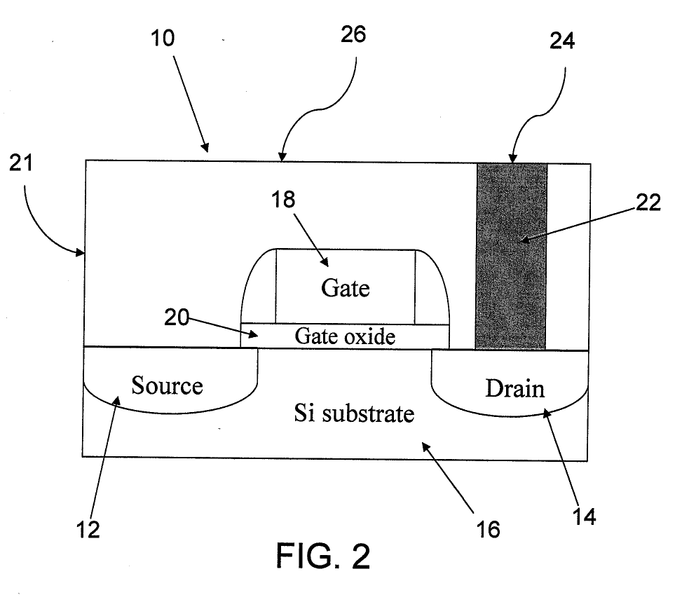

FIGS. 2 through 16 illustrate one exemplary process used to form the PRAM element 10. Specifically, these FIGS. represent a manufacturing method that utilizes self-assembled co-polymers to create the one or more columnar members 36. It should be understood, however, that the PRAM element 10 and devices incorporating the same may be manufactured using other semiconductor processing techniques. These include, by way of example, nano-imprinting, electron beam lithography, and ion patterning.

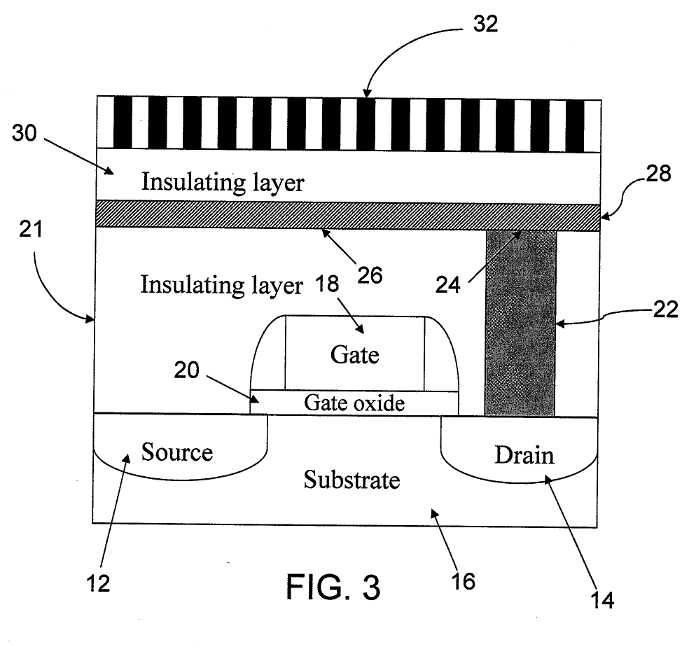

FIG. 2 illustrates a MOSFET 11 having a first electrode conductor 22 electrically coupled to the drain region 14 of the MOSFET 11. The first electrode conductor 22 terminates in an upper surface 24 that is substantially flush with an overlying insulator layer 21. With reference to FIG. 3, a layer 28 of phase change material is deposited over the upper surface 24 of the first electrode contact 22 and the upper surface 26 of the insulator 21. The layer 28 of phase change material may be deposited by heating the phase change material and spin coating the same over the insulator 21 and the upper surface 24 of the first electrode contact 22. Alternatively, the layer 28 of phase change material may be grown directly on the insulator 21 and first electrode contact 22. Still referring to FIG. 3, an insulating layer 30 is formed over the layer 28 of phase change material. The insulating layer 30 may be formed by spin coating an insulating material directly over the layer 28. Alternatively, the insulating layer 30 may be grown directly on the layer 28 using, for example, chemical vapor deposition with or without plasma enhancement. The insulating layer 30 may be formed from any number of insulators commonly utilized in the semiconductor arts. These include, by way of example, silicon dioxide, silicon nitride, fluorinated silicate glass, polyimide, hydrogen silsesquioxane, methyl silsesquioxane, methylated silica, fluorinated polyimide, poly(arylether), thermoset polymer, parylene, fluorinated amorphous carbon, and polytetrafluoroethylene.

Still referring to FIG. 3, a di-block copolymer layer 32 is formed over the insulating layer 30. In one aspect of the invention, the di-block copolymer layer 32 may be formed from two blocks. One example is polyisoprene (PI) and polystyrene (PS) which forms a self-assembled di-block copolymer (PI-PS) system. For example, a mixture of around 84.6% PS and 15.4% PI (on a weight basis) may be dissolved in a solvent such as toluene so as to create a 2% (by weight) PS-PI solution. The solution such as that described above may have an average molecular weight of around 81 kilograms/mol.

Another example of a di-block copolymer system includes poly(styrene-block-dimethylsiloxane) (P(S-b-DMS)). In this system, PDMS has a strong resistance to many types of reactive ion etch processes while polystyrene (PS) generally does not. Still other di-block copolymer systems may be used in accordance with the methods contemplated herein. For example, systems where one component is degraded preferentially in response to radiation may be employed (e.g., polymethylmethacrylate (PMMA) is known to be degraded on exposure to an electron beam or ultraviolet light while polystyrene (PS) is more stable). Block copolymer systems can also be used where one component is susceptible to chemical treatments to alter etching rates. For instance, in a PS system incorporating polyisoprene (PI) or polybutadiene (PB), PS may be etched at a higher rate than either PI or PB when the system is exposed to osmium tetroxide (OsO₄) and later subject to CF₄/O₂ reactive ion etching. It should be understood that the methods described herein may be used with any number of block copolymer systems known to those skilled in the art. For example, block copolymers can be made with different lengths of individual polymers leading to different cluster sizes and patterns. In this regard, by varying the lengths of individual polymers in the di-block system, the geometric profile and thus performance characteristics of the phase change columnar members (described below) may be modified or tuned.

The di-block copolymer layer 32 may be disposed onto the insulating layer 30 by spin coating the di-block copolymer solution onto the upper surface of the insulating layer 30. Alternatively, di-block copolymer constituents may be deposited on the insulating layer 30 by evaporation. For example, a PI-PS di-block copolymer system may be spun on an insulating layer 30 such as for instance, silicon dioxide. In forming the di-block copolymer layer 32, the solution is applied so as to form a thin monolayer on the upper surface of the insulating layer 30. For example, the thickness of the di-block copolymer layer 32 may be on the order of several nanometers. A monolayer thickness of the PI-PS di-block copolymer solution discussed above may produce a thickness of around 60 nm.

After the di-block copolymer solution is applied to the upper surface of the insulating layer 30, the structure is annealed in vacuum conditions for approximately twenty-four (24) hours at 155° C. to get phase separation between the PS and PI blocks. The structure is then immersed in DI water and exposed to ozone gas (e.g., 4% ozone in oxygen). The DI water is used to expand or swell the copolymer and helps the ozone to diffuse through the PS to break the double bonds in the PI polymer block. The bonds in the PI polymer block are broken after several minutes of exposure to the ozone (e.g., around 8 minutes). The device is then soaked in DI water for about twelve (12) hours to completely remove the PI regions within the di-block copolymer layer 32.

As yet another example of a di-block copolymer, PS-PMMA (polystyrene-b-polymethylmethacrylate) may be used to form the di-block copolymer layer 32. The PS-PMMA may be spin coated onto the upper surface of the insulating layer 30. The polymer layer may then be annealed by heating in a vacuum environment at about 1700 for twenty-four (24) hours. UV exposure followed by acetic acid treatment is then performed to remove the PMMA blocks.

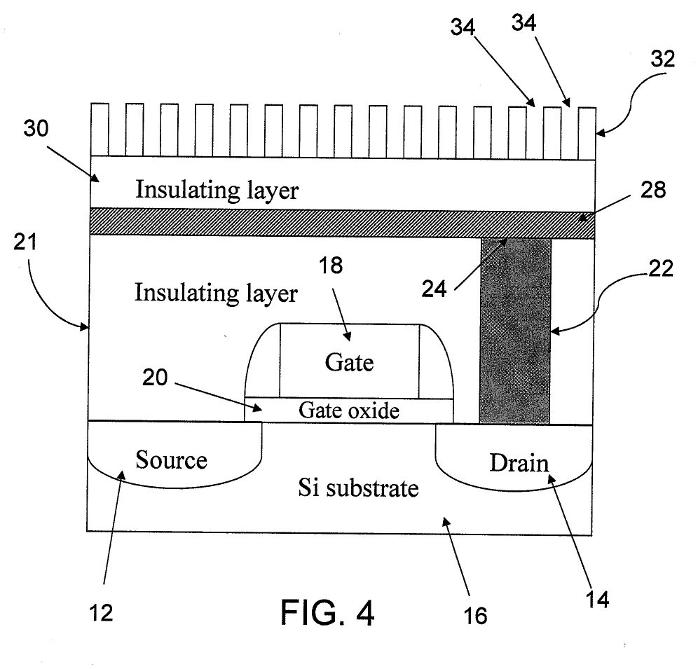

FIG. 4 illustrates the device after one block of the di-block copolymer layer 32 has been removed (e.g., a PI block). The removal of the single block from the di-block copolymer layer 32 leaves a plurality of holes or apertures 34 in the layer. Because of the arrangement of the di-block constituents within the layer 32, the plurality of holes 34 are arranged in a periodic or regular manner across the surface of the layer 32.

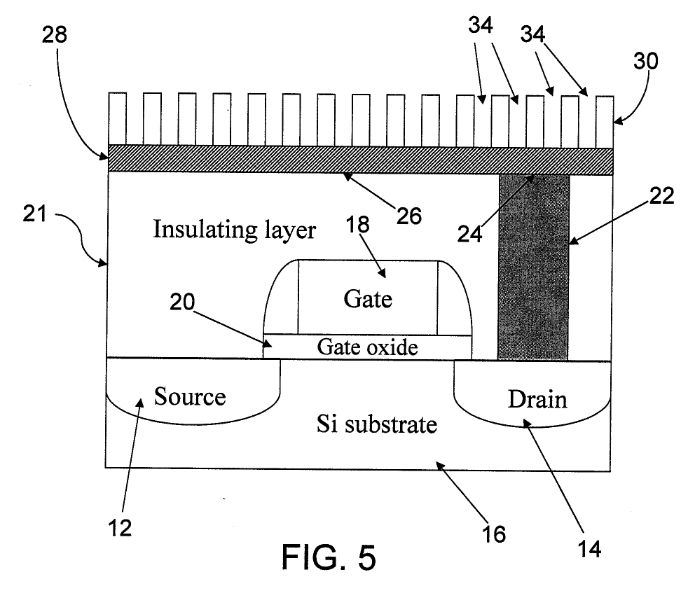

Next, with reference to FIG. 5, the pattern of holes 34 formed within the di-block copolymer layer 32 is then transferred to the underlying insulator layer 30. Transfer of the pattern of holes 34 may be accomplished by etching the structure of FIG. 4 with an etching agent. For example, reactive ion etching may be used to transfer the holes 34. In this process, the structure is placed in a vacuum chamber and ionized species such as CHF₃ or SF₆ is accelerated toward the surface. The ions react with the insulator layer 30 (e.g., oxide) which can then be removed to leave the pattern of holes 34 as shown in FIG. 5. In addition, as shown in FIG. 5, the polymer layer overlying the now patterned insulator layer 30 is removed. The polymer may be removed by exposure to oxygen plasma or the use of one or more liquid solvents that dissolve or otherwise remove the remaining polymer layer 32.

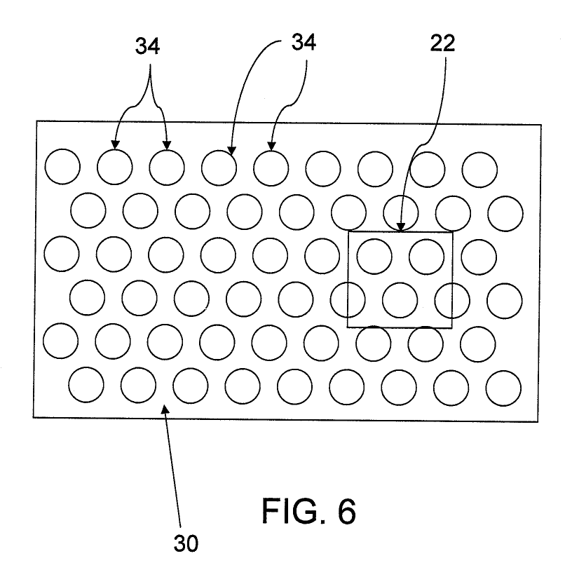

FIG. 6 illustrates a top down view of the structure shown in FIG. 5. The underlying layer 28 of phase change material is obscured from view for sake of clarity. In addition, the outline of the first electrode contact 22 is shown underneath the patterned insulator layer 30.

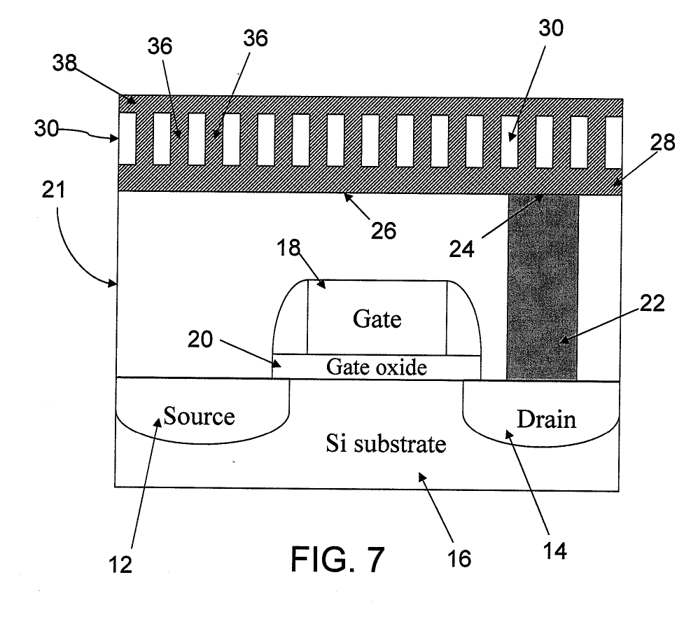

FIG. 7 illustrates a cross-sectional view of the structure of FIG. 5 after the plurality of holes 34 within the insulator layer 30 have been filled with phase change material to form a plurality of columnar members 36. Each columnar member 36 is formed from phase change material and takes the shape of the corresponding hole 34 formed in the insulator layer 30. For example, each columnar member 36 may have a circular cross-sectional shape. Of course, other cross-sectional profiles are also contemplated to fall within the scope of the invention (e.g., square, rectangular, oval, polygonal). In one aspect, the columnar members 36 may have diameters within the range of around 1 nm to around 1000 nm. FIG. 7 also illustrates a top layer 38 of phase change material overlying the plurality of columnar members 36. The top layer 38 of phase change material may be formed in the same process used to deposit phase change material in the holes 34. Alternatively, the top layer 38 may be deposited in a second, discrete process.

The columnar members 36 may be formed by selective chemical vapor deposition of elementary species of the phase change material. In this regard, the columnar members 36 may be built from the bottom up. In yet another alternatively, the phase change material may be heated in an oven or furnace to transform the same into a liquid or semi-liquid state. The phase change material may then be poured into the holes 34. Alternatively, liquid or semi-liquid phase change material may be wicked into the holes 34. The capillary action of the phase change material may aid in filling each hole 34. In one aspect, the columnar members 36 are oriented substantially parallel relative to the first electrode contact 22 (e.g., in a vertical manner as shown in the drawings).

While the process of forming the columnar members 36 has been described primarily using a di-block copolymer system, it should be understood that other methods capable of producing very small holes (e.g., nanometer sized holes) within an insulator layer 30 may also be used. For example, nano-imprint methods may be used to physically punch small pre-holes within the insulator layer 30. The complete holes 34 may then be liberated using standard etching methods. One exemplary nano-imprint lithography method is described in Austin et al., Fabrication of 5 nm Linewidth and 14 nm Pitch Features by Nanoimprint Lithography, Applied Physics Letters, Vol. 84, No. 26 (Jun. 28, 2004), which is incorporated by reference as if set forth fully herein. In yet another alternative, the holes 34 may be formed using projection electron beam lithography. One example of a low energy e-beam lithography method is described in Endo et al., Completion of the β tool and the Recent Progress of Low Energy E-Beam Proximity Projection Lithography, J. Vac. Sci. Technol. B 21(1), January/February 2003, which is incorporated by reference as if set forth fully herein. In still another alternative aspect, ion patterning may be used to form the holes 34 in the insulator. An example of focused ion beam lithography methods is disclosed in Matsui et al., Focused Ion Beam Applications to Solid State Devices, Nanotechnology 7 247-258 (1996), which is incorporated by reference as if set forth fully herein.

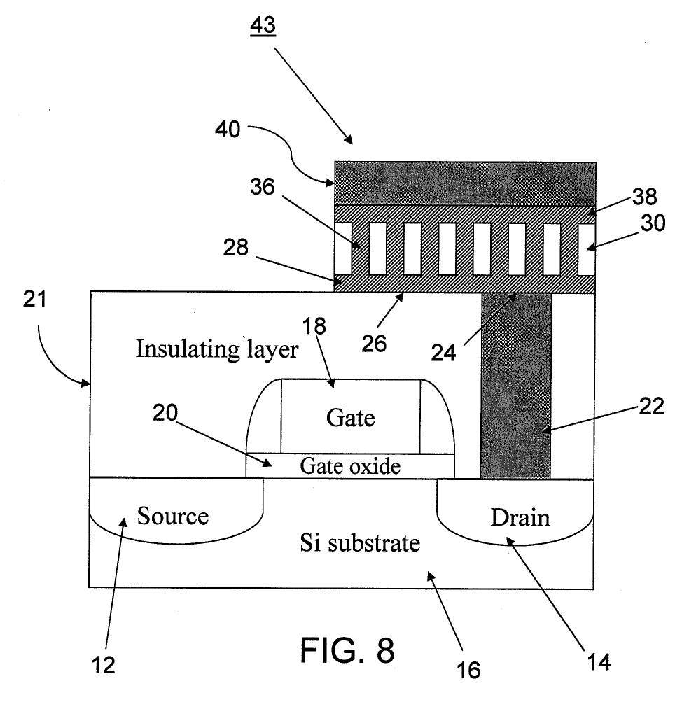

FIG. 8 illustrates a finalized embodiment of the memory cell 10 that includes a second electrode contact 40 in electrical contact with the layer 38 of phase change material. The second electrode contact 40 may be formed from a conductive metal such as, for instance, tungsten, molybdenum, and tantalum. In addition, FIG. 8 shows that the lateral size or extent of the layer 38, columnar members 36, insulator layer 30, and layer 28 of phase change material is reduced. Generally, the plurality of columnar members 36 interposed between the upper layer 38 and the lower layer 28 as is shown in FIG. 8 comprises one unit 43 or bit of the memory cell 10. The plurality of columnar members 36 are each separated from one another by an interstitial insulator layer 30. The insulator layer 30 confines heat generated through Joule heating to a relatively small area. In this regard, the insulator layer 30 in FIG. 8 acts as a thermal cage.

In addition, as is shown in the memory cell 10 of FIG. 8, the columnar members 36 are in direct contact with the upper and lower layers 38, 28, respectively, which are formed from the same phase change material as the columnar members 36. In this regard, there is no direct contact of the columnar members 36 with a dissimilar material (e.g., bottom or top electrode). As a result, the memory cell 10 avoids the problem of metal migration which leads to alloy-induced failure of the memory cell 10.

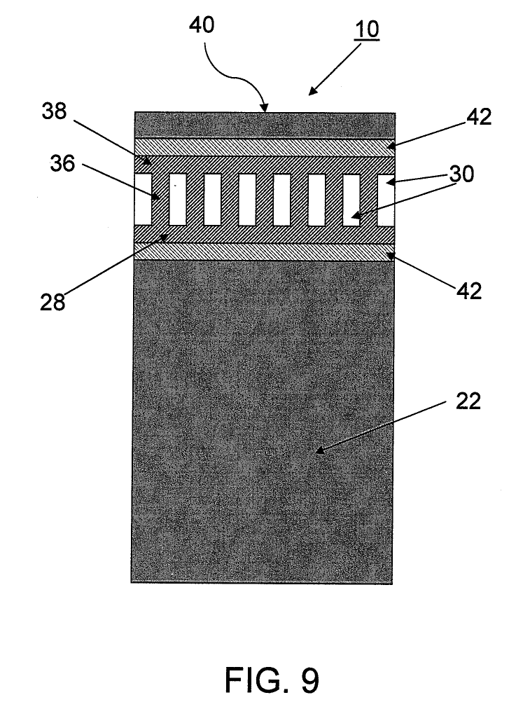

FIG. 9 illustrates a cross-sectional view of a portion of the memory cell 10 according to one embodiment. In this embodiment, an optional diffusion barrier 42 is interposed between the first electrode contact 22 and the layer 28 of phase change material. The optional diffusion barrier 42 is also interposed between the second electrode contact 40 and the layer 38 of phase change material. The diffusion barrier 42 is a thin layer of material that prevents or reduces metal migration into the phase change material. For example, the diffusion barrier 42 may be a thin layer of titanium nitride (TiN) or tungsten nitride (WN). In addition, in the embodiment of FIG. 9, the lateral dimension of the first electrode contact 22 and second electrode contact 40 is substantially contiguous with the lateral dimension of the layers 28, 38 as well as the interposed array of columnar member 36.

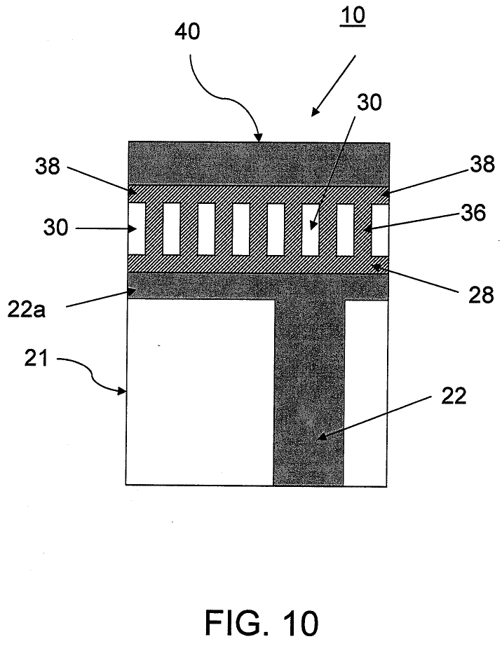

FIG. 10 illustrates a partial cross-sectional view of the memory cell 10 according to another aspect of the invention. As seen in FIG. 10, the first electrode contact 22 terminates in a generally planar contact surface 22a. The contact surface 22a may be formed integrally with the first electrode contact 22 or, alternatively, the contact surface 22a may be deposited as a separate, distinct layer that is in electrical contact with the underlying first electrode contact 22. The contact surface 22a may be formed from the same material used for the first electrode contact 22 (e.g., tungsten, molybdenum, or tantalum).

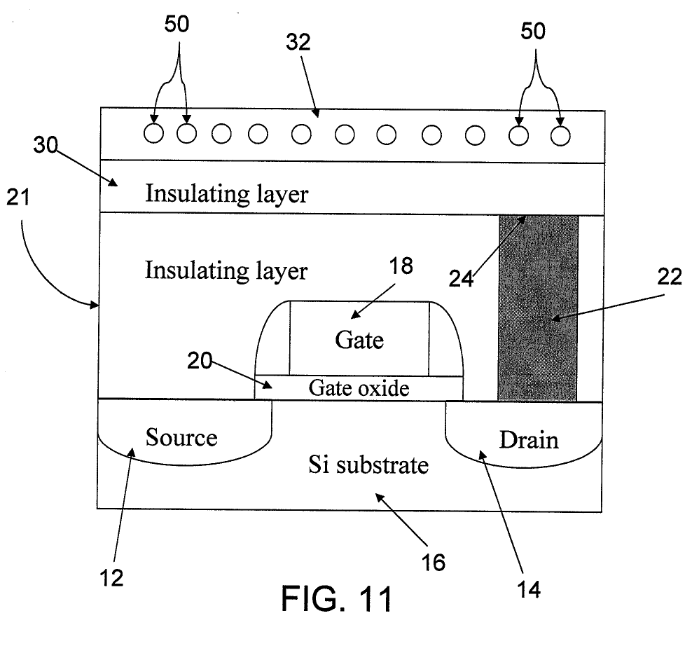

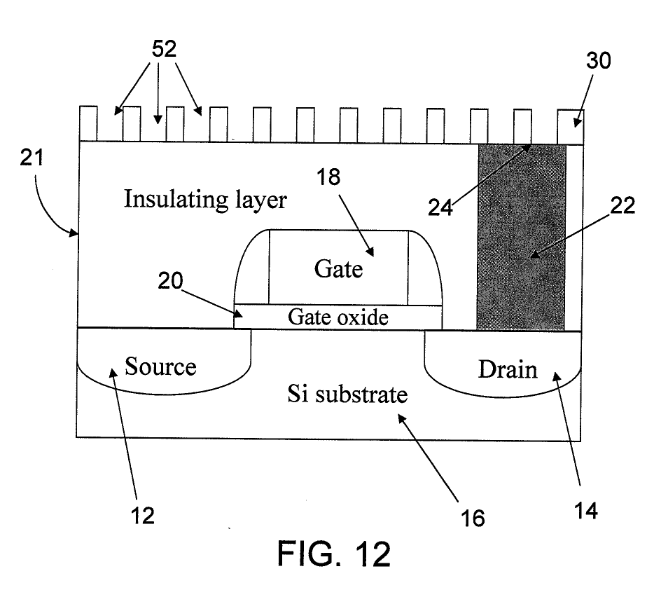

FIGS. 11-16 illustrates a process of manufacturing a memory element 10 according to another embodiment of the invention. In this embodiment, the di-block copolymer layer 32 that is deposited over the insulating layer 30 forms a plurality of laterally oriented (e.g., horizontal) “noodle” line patterns 50. With reference to FIG. 11, the noodle line patterns 50 actually form generally perpendicular to the plane of the paper. For example, in Harrison et al., Lithography With a Mask of Block Copolymer Microstructures, J. Vac. Sci. Technol. B 16(2) March/April, pp. 544-552 1998, discloses the use of parallel cylinders of polybutadiene (PB) in a polystyrene (PS) matrix to form parallel troughs in an underlying insulator substrate. The above-noted publication is incorporated by reference as if set forth fully herein. As in the previously discussed (vertical) embodiment, the di-block copolymer layer 32 is then exposed to an agent that removes one of the blocks from the di-block system. An etchant may then be exposed to the layer 32 having the one block removed. Because portions of the layer 32 are “free” of material, the etchant will form a plurality of lanes having a cross-sectional profile much like that disclosed in FIG. 4. That is to say, the layer 32 will have a plurality of open or empty lanes 52 that are regularly interposed between adjacent walls of polymer material. This pattern may then be transferred to the underlying insulating layer 30 as is described above. For example, reactive ion etching or the like may be used to transfer the pattern formed in the layer 32 to the underlying insulating layer 30 as is shown in FIG. 12.

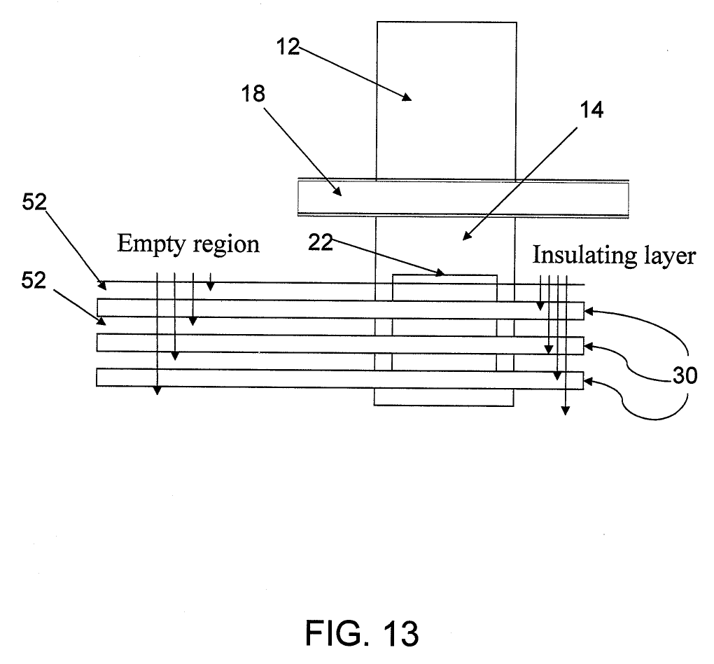

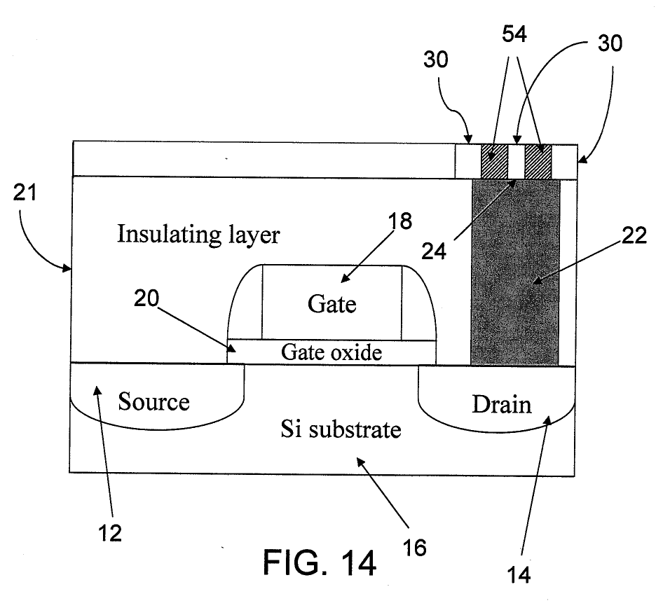

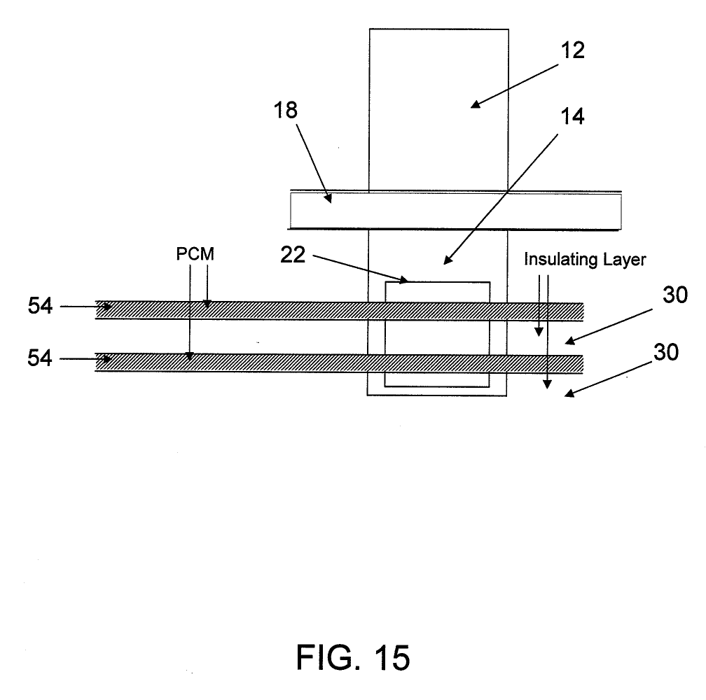

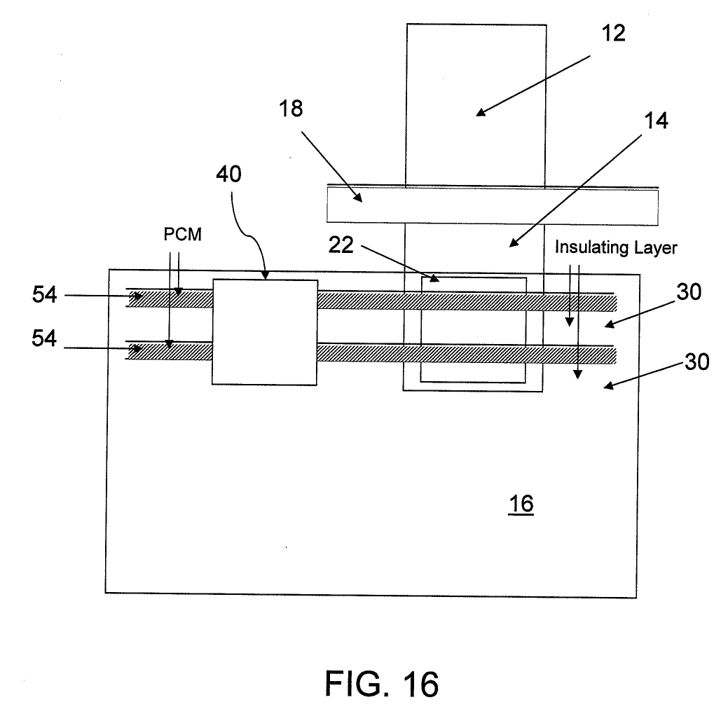

FIG. 13 is a top down view of the structure illustrated in FIG. 12. As seen in FIG. 13, the insulating layer 30 includes a plurality of spaced apart lanes 52 (e.g., lateral line patterns) that are formed from the empty regions created in the insulating layer 30 during the previous pattern transfer process. Also shown in FIG. 13 is the source 12, drain 14, gate electrode 18, and underlying first electrode contact 22. FIG. 14 illustrates a cross-sectional view of the structure of FIG. 12 with the lanes 52 being filled with phase change material 54. The lanes 52 may be filled by selective chemical vapor deposition of elementary species of the phase change material. Alternatively, the phase change material may be heated to transform the same into a liquid or semi-liquid state which can then be poured into the lanes 52. Alternatively, liquid or semi-liquid phase change material may be wicked into the lanes 52. The phase change material may be etched or subject to chemical-mechanical-polishing (CMP) form the generally planar arrangement illustrated in FIG. 14. FIG. 15 illustrates a top down view of the structure of FIG. 14. The lanes 52 illustrated in FIG. 13 are now filled with phase change material 54. FIG. 16 illustrates the structure of FIG. 15 with the addition of the second electrode contact 40 above the phase change material 54.

One advantage of the use of the di-block copolymer solution is that one can easily control the shape, size, density, and aspect ratio of the patterns that are transferred to the underlying insulating layer 30. Consequently, the line width and density of the PCM lines/columnar members may be custom tailored. In addition, as disclosed above, phase change lines (either as, for instance, columnar members or lanes) by be oriented vertically or horizontally. For PRAM technology to be widely implemented, it is desirable to have structures that can scale down to nanometer dimensions and thus high densities. In addition, the memory device should be able to reduce the amount of power consumption necessary to toggle between the bi-state phases (i.e., low reset current). Finally, future PRAM devices should have longevity, namely, the devices should retain the ability to switch between the two phases for a time period that is not shorter than current rival technologies like FLASH memory. The memory cells of the type disclosed herein offer the potential to satisfy all of these requirements.

The processes and structures described herein are largely described in the context of a single memory element 10 or memory bit. It should be understood that a plurality of such memory elements 10 would be used in commercial memory devices.

While embodiments of the present invention have been shown and described, various modifications may be made without departing from the scope of the present invention. For example, other multi-block polymer systems (e.g., tri-block and the like) may be used in place of the di-block systems disclosed herein. The invention, therefore, should not be limited, except to the following claims, and their equivalents.

What is claimed is:

1. A memory cell comprising:
a substrate including a source region and a drain region;
a gate electrode disposed between the source region and the drain region and separated from the source region and drain region via an oxide layer;
a first electrode contact coupled to the drain region at one end and terminating at a surface, the surface being coated with a layer of phase change material;
a second electrode contact having a surface coated with a layer of phase change material; and
at least one columnar member formed from a phase change material interposed between the phase change material layer of the first electrode and phase change material layer of the second electrode.

2. The memory cell of claim 1, wherein a plurality of columnar members formed from a phase change material are interposed between the phase change material layer of the first electrode contact and phase change material layer of the second electrode contact, and wherein the plurality of columnar members are separated from one another via an insulator material.

3. The memory cell of claim 1, wherein the at least one columnar member has a diameter within the range of 1 nm to 1000 nm.

4. The memory cell of claim 1, further comprising a diffusion barrier disposed between the first electrode and the layer of phase change material and between the second electrode and the layer of phase change material.

5. The memory cell of claim 4, wherein the columnar members have a cross-sectional shape selected from one of a circle, square, rectangle, oval, and polygonal.

6. The memory cell of claim 1, wherein the insulator material is selected from the group consisting of silicon dioxide, silicon nitride, fluorinated silicate glass, polyimide, hydrogen silsesquioxane, methyl silsesquioxane, methylated silica, fluorinated polyimide, poly(arylether), thermoset polymer, parylene, fluorinated amorphous carbon, and polytetrafluoroethylene.

7. The memory cell of claim 1, wherein the cross-sectional area of the at least one columnar member is less than the cross-sectional area of the phase change material layer of the first electrode contact and less than the cross-sectional area of the phase change material layer of the second electrode contact.

8. The memory cell of claim 1, wherein the cross-sectional area of the at least one columnar member is less than the cross-sectional area of the first electrode contact and less than the cross-sectional area of the second electrode contact.

9. A semiconductor memory device comprising a plurality of memory cells according to claim 1.

10. A method of making a memory cell comprising:
providing a substrate including a source region and a drain region and a gate electrode disposed between the source region and the drain region and separated from the source region and drain region via an oxide layer;
providing a first electrode contact coupled to the drain region at one end and terminating at a surface;
coating the surface of the first electrode contact with a layer of phase change material;
forming an insulating layer over the layer of phase change material;
patterning the insulating layer with at least one hole;
filling the at least one hole with phase change material;
coating the insulating layer with a layer of phase change material; and
providing a second electrode contact on the layer of phase change material disposed on the patterned insulating layer.

11. The method of claim 10, wherein the step of patterning the insulating layer with a plurality of holes comprises:
providing a self-assembled di-block copolymer layer on the insulating layer;
removing one block of the di-block copolymer layer so as to form a patterned di-block copolymer layer having a plurality of holes; and
transferring the pattern in the di-block copolymer layer to the insulating layer.

12. The method of claim 11, further comprising the step of removing the di-block copolymer layer.

13. The method of claim 10, wherein the step of patterning the insulating layer with a plurality of holes is accomplished by one of nano-imprinting, electron beam lithography, and ion patterning.

14. The method of claim 10, wherein the holes in the insulating layer have a diameter within the range of around 1 nm to around 1000 nm.

15. The method of claim 10, wherein the phase change material is a chalcogenide.

16. The method of claim 15, wherein the phase change material is selected from the group consisting of GeSbTe, AgInSbTe, InSe, SbSe, SbTe, InSbSe, InSbTe, GeSbSe, GeSbTeSe, and AgInSbSeTe.

17. A method of making a memory cell comprising:
providing a MOSFET operatively coupled to a PRAM element having at least one region of phase change material for read-write storage;
forming a bottom electrode contact electrically coupled to a drain region of the MOSFET;
coating the surface of the bottom electrode contact with a layer of phase change material;
forming an insulating layer over the layer of phase change material;
providing a self-assembled di-block copolymer layer on the insulating layer and removing one block of the di-block copolymer layer so as to form a patterned di-block copolymer layer having at least one hole;
transferring the pattern in the di-block copolymer layer to the insulating layer;
filling the at least one hole in the insulating layer with phase change material;
coating the insulating layer with a layer of phase change material; and
providing a top electrode contact on the layer of phase change material disposed on the patterned insulating layer.

18. The method of claim 17, wherein the at least one hole in the insulating layer has a diameter within the range of around 1 nm to around 1000 nm.

19. The method of claim 17, wherein the phase change material is a chalcogenide.

20. A semiconductor memory device comprising a plurality of memory cells formed according to method of claim 17.
